(19) United States
(12) Patent Application Publication
(10) Pub. No.: US 2017/0288698 A1
(43) Pub. Date: Oct. 5, 2017

(54) POWER SAVING FOR BIT FLIPPING DECODING ALGORITHM IN LDPC DECODER

(71) Applicant: Silicon Motion Inc., Hsinchu County (TW)

(72) Inventor: Jian-Dong Du, Taoyuan City (TW)

(21) Appl. No.: 15/083,310

(22) Filed: Mar. 29, 2016

(51) Int. Cl. H03M 13/11

(52) U.S. Cl. CPC H03M 13/1108; H03M 13/1174

(57) ABSTRACT

A method for determining when to end a bit flipping algorithm during hard decision soft decoding in a low density parity check (LDPC) decoder includes: selecting a certain number of iterations as a first threshold; when the first threshold is reached, determining a highest variable node codeword for each iteration performed so far; comparing the highest variable node codewords with a second threshold; and when the value of the highest variable node codewords is less than or equal to the second threshold, ending the bit flipping algorithm.

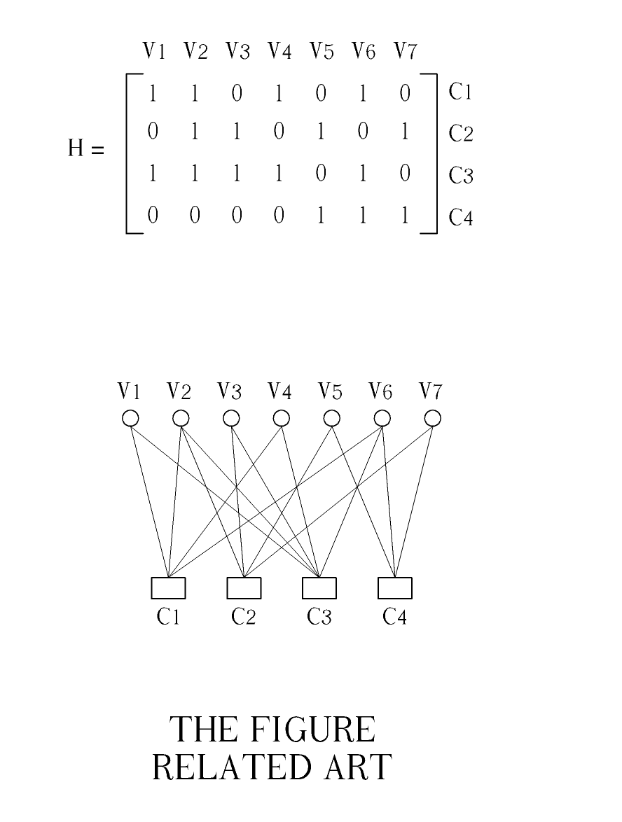

### BACKGROUND OF THE INVENTION

### 1. Field of the Invention

This invention is related to hard decoding for a low-density parity check (LDPC) decoder, and more particularly, to a bit flipping algorithm with a power saving scheme.

### 2. Description of the Prior Art

Low-density parity check (LDPC) decoders use a linear error correcting code with parity bits. Parity bits provide a decoder with parity equations which can validate a received codeword. For example, a low-density parity check is a fixed length binary code wherein all the symbols added together will equal zero.

During encoding, all data bits are repeated and transmitted to encoders, wherein each encoder generates a parity symbol. Codewords are formed of k information digits and r check digits. If the length of the codeword is n then the information digits, k, will equal n−r. The codewords can be represented by a parity check matrix, which consists of r rows (representing equations) and n columns (representing digits), and is represented in the FIGURE. The codes are called low-density because the parity matrix will have very few ‘1’s in comparison to the number of ‘0’s. During decoding, each parity check is viewed as a single parity check code, and is then cross-checked with others. Decoding occurs at check nodes, and cross-checking occurs at variable nodes.

LDPC engines support three modes: hard decision hard decoding, soft decision hard decoding, and soft decision soft decoding. The FIGURE illustrates the parity check matrix H and a Tanner graph, which is another way of representing the codewords, and is used to explain the operation of the LDPC decoder for hard decision soft decoding when using a bit flipping algorithm.

The check nodes, which are represented by the square boxes, are the number of parity bits; and the variable nodes, which are represented by the circular boxes, are the number of bits in a codeword. If a code symbol is involved in a particular equation, aline is drawn between the corresponding check node and variable node. ‘Messages’, which are estimates, are passed along the connecting lines, and combined in different ways at the nodes. Initially, the variable nodes will send an estimate to the check nodes on all connecting lines containing a bit believed to be correct. Each check node then takes all the other connected estimates, makes new estimates for each variable node based on this information, and passes the new estimate back to the variable nodes. The new estimate is based on the fact that the parity check equations force all variable nodes connected to a particular check node to sum to zero.

The variable nodes receive the new information and use a majority rule (a hard decision) to determine if the value of the original bit they sent was correct. If not, the original bit will be ‘flipped’. The bit is then sent back to the check nodes, and these steps are repeated for a predetermined number of iterations or until the parity check equations at the check nodes are satisfied. If these equations are satisfied (i.e. the value calculated by the check nodes matches the value received from the variable nodes) then Early Termination can be activated, which allows the system to exit the decoding process before the maximum number of iterations is reached.

The number of iterations is limited by an amount of error bits. Above a certain number of iterations, the error bits increase dramatically. At this point, it is advisable for the system to switch to a different decoding mode. The decision when to change modes (e.g. from bit flipping to soft decision soft decoding) is made according to the performance of the decoder, as the exact amount of error bits is unknown.

The bit flipping algorithm described above is a low power decoding method. Hard decision soft decoding can also employ other decoding algorithms such as those used by the N2 decoder and N6 decoder. These different decoding algorithms will yield different results, and there are various advantages and disadvantages associated with each one. If it can be determined at what point the correctable bit rate of the bit flipping algorithm starts to decrease, then the type of decoding can be switched. The low power advantage of the bit flipping decoder at fewer raw error bits is preserved, and the greater correctable rate of the other decoders can be utilized at the exact point the bit flipping decoder's performance starts to degrade.

### SUMMARY OF THE INVENTION

It is therefore an objective of the present invention to provide a method for determining the exact point at which the performance of the bit flipping algorithm starts to degrade, and using this information to change the decoding algorithm to one with a higher correctable rate.

The present invention therefore discloses a method for determining when to end a bit flipping algorithm during hard decision soft decoding in a low density parity check (LDPC) decoder. The method comprises: selecting a certain number of iterations as a first threshold; when the first threshold is reached, determining a highest variable node codeword for each iteration performed so far; comparing the highest variable node codewords with a second threshold; and when the value of the highest variable node codewords is less than or equal to the second threshold, ending the bit flipping algorithm decoding.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The FIGURE illustrates a parity check matrix H and a Tanner graph.

### DETAILED DESCRIPTION

As described above, the aim of the present invention is to prevent the bit flipping algorithm from going through too many useless iterations, and to provide a clear point at which the decoding algorithm should be switched for hard decision soft decoding.

The present invention therefore provides a dynamic bit flipping method wherein there is no predetermined number of iterations. Instead, a performance parameter is used as a benchmark for determining a maximum number of iterations.

During bit flipping, the variable nodes use majority rule to determine correct information by finding the largest variable node, flipping the original bit and determining whether the check node becomes zero. After a certain number of iterations, all check nodes should be zero, unless there are uncorrectable errors which require a different decoding algorithm.

The column weight of a variable node is defined as the number of ‘ONES’ in a column of the parity check matrix illustrated in the FIGURE, and therefore represents the greatest error at the variable node. As shown in the FIGURE, the column weight also represents how many check nodes each variable node is coupled to. Column weight is used herein as a measure for determining when to terminate bit flipping.

A value, t, is used to set a minimum number of iterations performed before the column weight is used to measure performance. In the example given herein, t is selected as 3. This is because the codeword is unlikely to be satisfied in a first or even second iteration. The exact value of t is not fixed, however, and can be changed according to different requirements. Taking t as 3, and taking an iteration at which the column weight is first used to measure performance as i (a current iteration), the decoder will undergo a first iteration i−2 and a second iteration i−1.

As described above, the bit flipping algorithm considers the largest codeword at the variable nodes and flips an original bit. At this point, the system will also compare a value of the largest variable node codeword for the first iteration i−2, the second iteration i−1, and the current iteration i, respectively, with the corresponding column weight divided by 2. If the value for each iteration is less than or equal to the corresponding column weight divided by 2, this indicates that the decoding mode should switch. If the value is higher, the bit flipping algorithm can go through another iteration. This is illustrated below.

If [mᵢ₋ₜ, . . . , mᵢ]<floor (column weight/2) then terminate bit flipping.

From the above, mᵢ is the maximum threshold (largest variable codeword) at the i-th iteration, and t describes the number of iterations which are considered, wherein t is adjustable.

Once it is determined that the highest variable node codewords are less than or equal to the column weight divided by 2 for a set number of iterations, this represents that the bit flipping algorithm has reached an unresolvable number of error bits and that the decoding algorithm should be switched.

The present scheme therefore offers a chance to save power during bit flipping by only performing the algorithm for a certain number of iterations. By using column weight as a performance parameter, a time for ending the bit flipping can be quickly determined, and another decoding algorithm can be selected.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for determining when to end a bit flipping algorithm during hard decision soft decoding in a low density parity check (LDPC) decoder, the method comprising:
selecting a certain number of iterations as a first threshold;
when the first threshold is reached, determining a highest variable node codeword for each iteration performed so far;
comparing the highest variable node codewords with a second threshold; and
when the value of the highest variable node codewords is less than or equal to the second threshold, ending the bit flipping algorithm.

2. The method of claim 1, wherein the first threshold is dynamic.

3. The method of claim 1, further comprising:
when the value of the highest variable node codewords is greater than the second threshold, continuing the bit flipping algorithm for one more iteration.

4. The method of claim 1, wherein the second threshold is a column weight of the highest variable node for the current iteration divided by 2.

5. The method of claim 1, wherein the step of ending the bit flipping algorithm further comprises:
utilizing another soft decoding hard decision algorithm in the LDPC decoder.
